(19) United States
(12) Patent Application Publication
(10) Pub. No.: US 2012/0192926 A1
(43) Pub. Date: Aug. 2, 2012

(54) SOLAR ARRAY

(76) Inventors: Tatsuji Kambara, Higashiomi (JP); Hiroaki Hirata, Higashiomi (JP)

(21) Appl. No.: 13/150,513

(22) Filed: Jun. 1, 2011

(30) Foreign Application Priority Data
Jul. 20, 2010 (JP) 2010-162379

(51) Int. Cl. H01L 31/048

(52) U.S. Cl. 136/251

(57) ABSTRACT

A solar array includes a plurality of solar modules arrayed along at least one of an X-direction and a Y-direction perpendicular to the X-direction in a not-overlapped state with rear surfaces of the solar modules being directed downwards, and a mounting member arranged between corners of the solar modules adjacent to each other. The mounting member includes a first member extending in at least one of the X-direction and the Y-direction, a second member including a support portion supporting the rear surface of the solar module, a third member including a clamping portion clamping the solar module in cooperation with the support portion of the second member, and a fixing member fixing the second member and the third member to the first member. The second member and the third member are movable along a lengthwise direction of the first member.

### CROSS-REFERENCE TO RELATED APPLICATION

The present application claims priority under 35 U.S.C. §119 to Japanese Patent Application No. 2010-162379, filed on Jul. 20, 2010, entitled “SOLAR ARRAY”. The content of which is incorporated by reference herein in its entirety.

### FIELD OF THE INVENTION

The present invention relates to a solar array.

### BACKGROUND

A solar array includes a plurality of solar modules and a mount for fixing the plural solar modules. Generally, a long and narrow structural member is installed as the mount on a roof of a house, and the solar modules are fixed at opposite sides of each module to the mount over its entire length.

Also, as disclosed in Japanese Unexamined Patent Application Publication No. 2004-324181, a solar array is proposed in which solar modules are fixed to a roof by using small fixing members instead of the long and narrow structural member.

In the proposed solar array, however, respective sides of adjacent solar modules positioned to face each other are fixed by using the fixing member. Accordingly, the fixing member has to support, on each side fixing the corresponding side of the solar module, the dead load, the snow load, and the wind load, which are applied to about a half area of one solar module. Thus, two or more fixing members are required for one solar module, and a larger number of man-hours for installation work and a larger amount of materials are needed in some cases.

Further, when trying to arrange the above-mentioned small fixing members at corners of the solar module, there is a possibility that, if the roof is distorted, the solar modules cannot be arrayed in a good external appearance.

For that reason, it is a need for a solar array, which can reduce the number of fixing members used for fixing solar modules, and which enables the fixing members and the solar modules to be easily arranged at suitable positions.

### SUMMARY

A solar array according to one embodiment of the present invention includes a plurality of solar modules arrayed along at least one of an X-direction and a Y-direction perpendicular to the X-direction in a not-overlapped state with rear surfaces of the solar modules being directed downwards, and a mounting member arranged between corners of the solar modules adjacent to each other. The mounting member includes a first member extending in at least one of the X-direction and the Y-direction, a second member positioned on the first member and including a support portion supporting the rear surface of the solar module, a third member positioned on the second member and including a clamping portion clamping the solar module in cooperation with the support portion of the second member, and a fixing member vertically penetrating through the second member and the third member and fixing the second member and the third member to the first member. The second member and the third member are movable along a lengthwise direction of the first member.

### BRIEF DESCRIPTION OF THE DRAWINGS

FIG. 1A is a perspective view of a solar array 101 according to a first embodiment.

FIG. 1B is a sectional view taken along a line A-A′ in FIG. 1A.

FIG. 1C is a partial enlarged view of a portion B in FIG. 1A.

FIG. 2A is a plan view of a solar module 3 used in the solar array 101 of FIG. 1.

FIG. 2B is a sectional view taken along a line C-C′ in FIG. 2A.

FIGS. 3A and 3B are exploded perspective views of a mounting member 4 used for mounting the solar array 101 illustrated in FIG. 1, when viewed from top and bottom, respectively.

FIG. 3C is a perspective view of the mounting member 4 illustrated in FIG. 3A.

FIG. 3D is a sectional view taken along a line F-F′ in FIG. 3C.

FIG. 4 is a perspective view to explain a mounted state of the mounting member 4 illustrated in FIG. 3.

FIGS. 5A, 5B, 5C and 5D are sectional views to successively explain installation steps of the solar array 101 illustrated in FIG. 1.

FIG. 6A is a perspective view to explain an installation step of the solar array 101 illustrated in FIG. 1.

FIG. 6B is a sectional view taken along a plane passing a midpoint of a first member 21 in FIG. 6A in a widthwise direction thereof.

FIG. 6C is a partial enlarged view of a portion G in FIG. 6B.

FIG. 7 is a side view illustrating an installation method for the solar array 101 illustrated in FIG. 1.

FIG. 8A illustrates a state where a solar array 201 according to a second embodiment is installed on a sloped surface as a base structure, and it is a perspective view when looking at the solar array 201 from the light receiving surface side.

FIG. 8B is a partial enlarged view of a portion A in FIG. 8A.

FIG. 8C is

FIG. 9 illustrates a section of the solar array 201 illustrated in FIG. 8; specifically, FIG. 9A is a sectional view taken along a line C-C′ in FIG. 8B, and FIG. 9B is a sectional view taken along a line D-D′ in FIG. 8B.

FIG. 10 illustrates the solar array 201 illustrated in FIG. 8; specifically, FIG. 10A is an exploded perspective view of a portion A in FIG. 8A, FIG. 10B is a perspective view of an engagement member 25 when viewed from a different direction, and FIG. 10C is a perspective view of a support 22 when viewed from a different direction.

FIG. 11A is a perspective view of a part of a support rail in a solar array 301 according to a third embodiment.

FIG. 11B is a sectional view, partly exploded, of the solar array 301.

FIG. 11C is a partial sectional view of a solar array 401 according to a fourth embodiment.

FIGS. 12A and 12B are each a perspective view of a height adjusting means M used in a solar array 501 according to a fifth embodiment.

FIG. 12C is a partial sectional view of the solar array 501.

FIG. 13A is a perspective view of a height adjusting means M used in a solar array 601 according to a sixth embodiment.

FIG. 13B is a partial sectional view of the solar array 601.

FIGS. 14A and 14B are exploded perspective views of the solar array 601 illustrated in FIG. 13, when viewed from top and bottom, respectively.

FIG. 15 illustrates a solar array 701 according to a seventh embodiment, and it is a partial enlarged view corresponding to FIG. 1C.

### DETAILED DESCRIPTION

Solar arrays according to embodiments of the present invention will be described below with reference to the drawings.

### First Embodiment

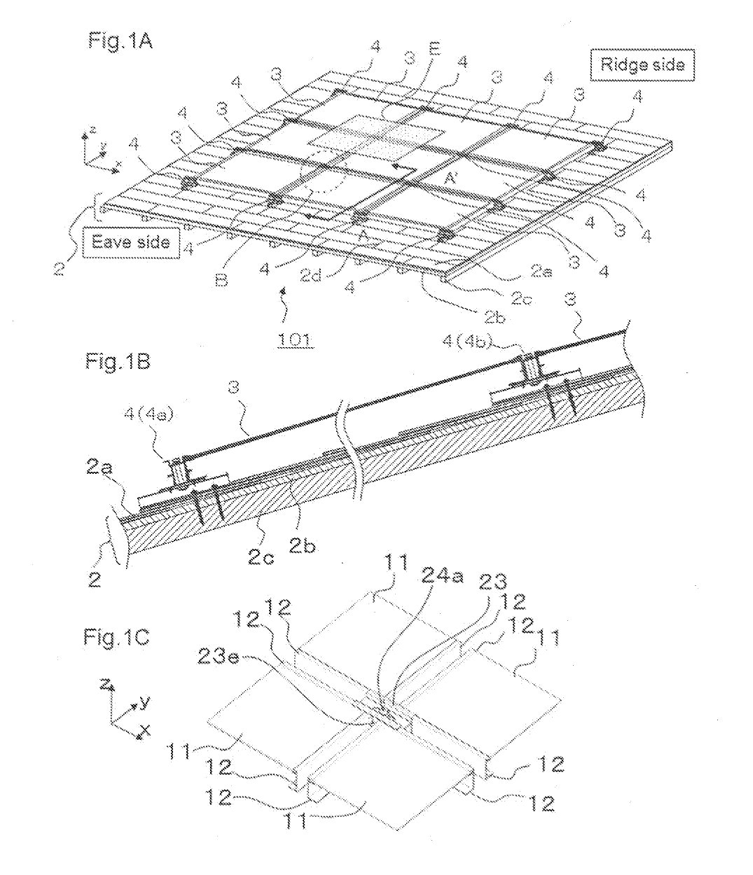

As illustrated in FIGS. 1A and 1B, a solar array 101 includes a plurality of solar modules 3 and mounting members 4. The solar array 101 is fixed onto a base structure 2 (roof surface) that includes a shingle 2a, a sheathing 2b, and a rafter 2c. The plural solar modules 3 are arrayed in a state not overlapping with each other with their rear surfaces positioned on the lower side. In this embodiment, as illustrated in FIG. 1A, the plural solar modules 3 are arrayed along two directions, i.e., a Y-direction corresponding to a direction in which the sloped surface 2 is sloped, and an X-direction perpendicular to the Y-direction.

<Solar Module>

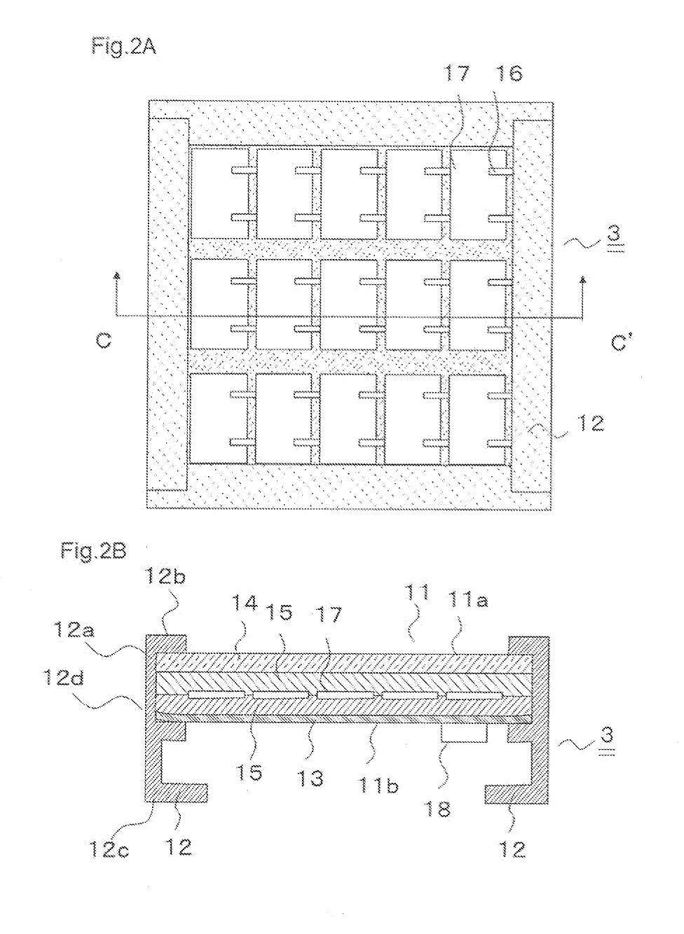

As illustrated in FIG. 2, each of the solar modules 3 includes a solar panel 11 and a frame 12.

The solar panel 11 includes, as illustrated in FIG. 2B, a light receiving surface 11a (one principal surface of a light-transmissive base plate 14) for primarily receiving light, and a light non-receiving surface 11b (one principal surface of a rear-surface protective member 13) that is positioned on the reverse side with respect to the light receiving surface 11a.

The solar panel 11 includes the light-transmissive base plate 14, a pair of filling materials 15, a plurality of solar (cell) elements 17, the rear-surface protective member 13, and a terminal box 18, which are successively arranged from the side defining the light receiving surface 11a.

The light-transmissive base plate 14 functions as a base plate for the solar module 3. The pair of filling materials 15 is made of, e.g., a thermosetting resin. The plural solar elements 17 are protected by the filling materials 15 surrounding them and are electrically connected to each other by inner leads 16. The rear-surface protective member 13 protects the rear surface of the solar module 3. The terminal box 18 takes out an output power obtained with the solar elements 17 to the outside.

The light non-receiving surface 11b is not limited to a surface in the form not receiving light at all. The light non-receiving surface 2b may receive part of light incoming from the side defining the light non-receiving surface 11b by, for example, using a light-transmissive material to form each of the rear-surface protective member 13 and the filling material 15, the latter being positioned between the solar elements 17 and the rear-surface protective member 13.

The solar elements 17 are each formed of a substrate made of, e.g., single-crystal silicon or polycrystalline silicon. When the silicon substrates are used, the adjacent silicon substrates may be electrically connected to each other by using the inner leads 16 as described above.

The type of the solar element 17 is not limited to particular one. The solar element 17 may be formed by using, e.g., a thin-film solar cell made of amorphous silicon, a CIGS solar cell, a CdTe solar cell, or a solar cell obtained by forming the thin-film amorphous on a crystalline silicon substrate. For example, the solar cell made of amorphous silicon, CIGS or CdTe can be formed by appropriately stacking an amorphous silicon layer, a CIGS layer, or a CdTe layer on a light-transmissive substrate in combination with transparent electrodes, etc.

The terminal box 18 includes a box body, a terminal plate arranged in the box body, and an output cable for leading power to the outside of the box body. The box body can be made of, e.g., a modified polyphenylene ether resin (modified PPE resin) or a polypnenylene oxide resin (PPO resin).

The frame 12 has the function of holding the solar panel 11. As illustrated in FIGS. 2A and 2B, the frame 12 is a long member for reinforcing an outer periphery of the solar panel 11. In more detail, the frame 12 includes a fitting portion 12a, a frame upper surface 12b, a frame lower surface 12c, and a frame lateral surface 12d. The fitting portion 12a is fitted to the solar panel 11 when the solar array 1 is installed as described later. The frame upper surface 12b is a principal surface of the frame 12, which is positioned on the side receiving the sunlight. The frame lower surface 12c is a principal surface of the frame 12, which is positioned on the reverse side with respect to the frame upper surface 12b. The frame lateral surface 12d interconnects the frame upper surface 12b and the frame lower surface 12c, and it is directed outwards. The frame 12 can be manufactured, for example, by extruding aluminum.

In the solar module 3 constituting the solar array 1, the frame 12 positioned on the eave side is called an eave-side frame 12e hereinafter. In this embodiment, the eave side implies the lower side in the Y-direction.

<Mounting Member>

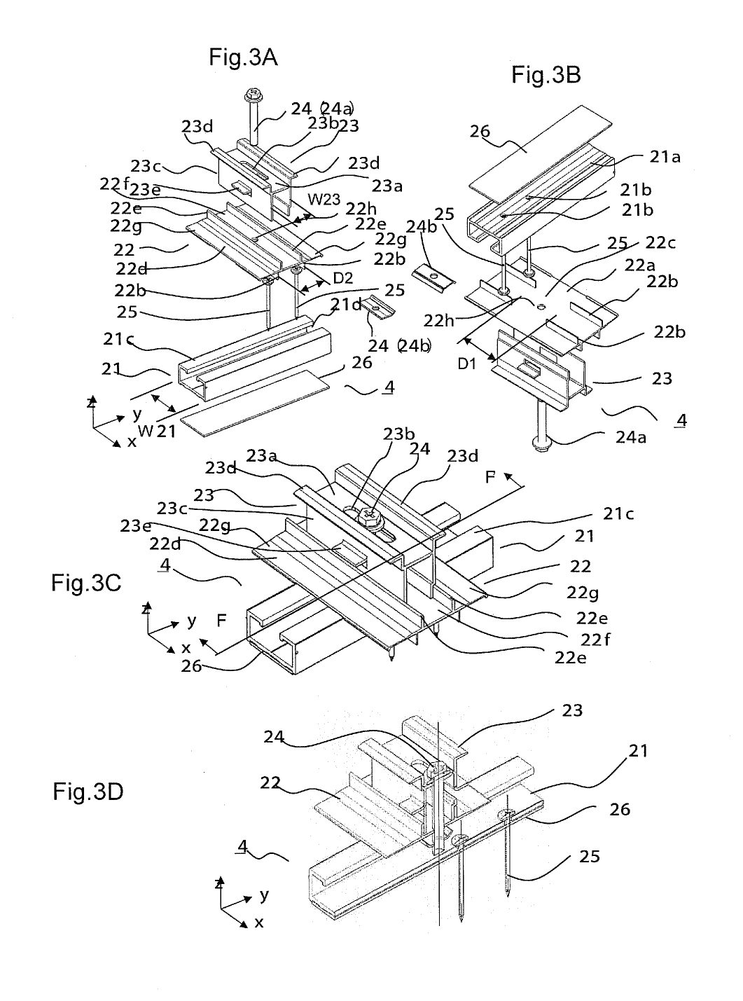

As illustrated in FIGS. 1A and 1C, the mounting member 4 is arranged at a position among corners of the adjacent solar modules 3. The mounting member 4 includes, as illustrated in FIGS. 3A and 3B, a first member 21, a second member 22, a third member 23, a fixing member 24, wood screws 25, and an adhesive member 26.

As illustrated in FIGS. 3C and 3D, the third member 23 is arranged on the second member 22, and the second member 22 and the third member 23 are fixed onto the first member 21 by using the fixing member 24.

Further, the wood screws 25 have the function of fixing the first member 21 to the base structure 2. The adhesive member 26 has the function of sealing off a clearance between the first member 21 and the base structure 2 and reducing penetration of rain into the inner side of the base structure 2 along the wood screws 25.

Structures of the first member 21, the second member 22, the third member 23, and the fixing member 24 will be described in detail below with reference to FIG. 3.

In this embodiment, the first member 21 is extended in the Y-direction. The second member 22 is positioned on first member 21 and includes a support portion for supporting the rear surface of the solar module 3. The third member 23 is positioned on the second member 22 and includes a clamping portion to clamp the solar module 3 in cooperation with the support portion of the second member 22. In this embodiment, the support portion is a part of a second principal surface 22d described later, and the clamping portion is a press-fixing portion 23d described later. Further, the fixing member 24 fixes the second member 22 and the third member 23 to the first member 21, and it vertically penetrates through the second member 22 and the third member 23.

In this embodiment, the second member 22 and the third member 23 are movable along a lengthwise direction of the first member 21.

The mounting member 4 thus constructed can fix various solar modules 3 having different sizes in the Y-direction. Also, the fixing position of the mounting member 4 can be finely adjusted depending on a variation of tolerances in the Y-direction among the plural solar modules 3. Therefore, the number of the mounting members 4 needed to fix one solar module 3 can be reduced, and installation accuracy required in fixing the solar module 3 by the mounting member 4 can be reduced. As a result, a cost reduction and an improvement of installation efficiency can be realized.

Be it noted that the expression vertical direction used here implies a Z-direction that is orthogonal to both the X-direction and the Y-direction.

Further, in this embodiment, the first member 21 has a shape elongate with its lengthwise direction being in the Y-direction. More specifically, the first member 21 is a rectangular rail having a substantially U-shaped cross-section.

In addition, the first member 21 has a principal surface 21a and through-holes 21b. The principal surface 21a is positioned on the reverse side with respect to an opening in the substantially U-shaped cross-section, and it faces the base structure 2. The through-holes 21b are formed in the principal surface 21a, and the wood screws 25 are inserted in the through-holes 21b. The first member 21 is fixed to the base structure 2 by the wood screws 25 inserted in the through-holes 21b.

The principal surface 21a may have a recessed and/or projected portion extending in the lengthwise direction of the first member 21. In such a case, particularly, the through-holes 21b may be formed in the recessed portion of the principal surface 21a. With the principal surface 21a having the recessed and/or projected portion, when the dead load, the snow load, and the wind load are applied to the mounting member 4, the adhesive member 26 can be more surely avoided from protruding to the surrounding of the first member 21. In addition, the adhesive member 26 having an appropriate thickness can be left to stand around the wood screws 25, thereby reducing penetration of water into the inner side.

In this embodiment, the first member 21 includes a pair of resting portions 21c extending outwards from the opening in the substantially U-shaped cross-section, and a gap 21d positioned between the resting portions 21c. The second member 22 has a bolt hole 22h which is formed substantially at a center thereof and which allows insertion of the fixing member 24 therethrough. The resting portions 21c support the second member 22, and the gap 21d allows the fixing member 24 to be moved when the fixing member 24 is loosened, which has been inserted through the bolt hole 22h of the second member 22 to fix the second member 22 onto the first member 21. Thus, the second member 22 is made movable in the Y-direction with the presence of the gap 21d.

The first member 21 can be manufactured by extruding a metal, such as an aluminum alloy. When the first member 21 is made of a material other than the aluminum alloy, the first member 21 can be manufactured, for example, by roll-forming or bending a stainless steel plate or a plated steel plate with rolls or a bender.

Further, in this embodiment, before the second member 22 and the third member 23 are fixed to the first member 21 by the fixing member 24, the second member 22 is movable in the Y-direction and the third member 23 is movable in the X-direction and the Y-direction. Accordingly, positioning of the solar module 3 can be finely adjusted in the X- and Y-directions.

In this embodiment, the second member 22 includes, in its first principal surface 22a facing the first member 21, a first guide portion 22c for guiding movement of the second member 22 in the lengthwise direction of the first member 21 (i.e., in the Y-direction). As a result, the second member 22 can be more easily moved in the Y-direction.

Moreover, in this embodiment, the second member 22 includes, in its second principal surface 22d facing the third member 23, a second guide portion 22f for guiding movement of the third member 23 in the lengthwise direction of the second member 22 (i.e., in the X-direction). The third member 23 has a through-hole 23b through which the fixing member 24 is inserted, the through-hole 23b allowing the third member 23 to be moved with respect to the fixing member 24 before the third member 23 is fixed to the first member 21. As a result, the third member 23 can be easily moved in the X-direction. The through-hole 23b is, e.g., a hole elongate in the X-direction.

More specifically, the second member 22 is an elongate plate-like member having the first principal surface 22a and the second principal surface 22d, and it includes a plurality of fins disposed on both the principal surfaces and extending in the lengthwise direction thereof. The second member 22 is assembled such that the lengthwise direction of the second member 22 is perpendicular to the lengthwise direction of the first member 21.

To describe in more detail, the second member 22 includes, on the first principal surface 22a facing the first member 21, a pair of first projections 22b (first fins) extending in the lengthwise direction thereof (i.e., in the X-direction). The first guide portion 22c is provided by the pair of first projections which are erected from the first principal surface 22a of the second member 22. The pair of first projections are arranged on the second member 22 in oppositely spaced relation in the widthwise direction of the first member 21 (i.e., in the X-direction). A distance D1 between the pair of first projections spaced in the widthwise direction of the first member 21 is equal to or larger than a widthwise size W21 of the first member 21. With such a simple structure, the above-mentioned movement of the second member 22 in the Y-direction can be facilitated.

Engagement of the first projections 22b with the first member 21 enables the second member 22 to slide in the Y-direction without rotating on the first member 21. Also, when the fixing member 24 is fastened, the second member 22 can be more surely avoided from being rotated and being dislocated.

Further, the first projections 22b contribute to increasing the section modulus in a cross-section perpendicular to the lengthwise direction of the second member 22 and can ensure the strength supporting the solar module 3 from below.

In this embodiment, the pair of first projections 22b arranged in a row in the X-direction is provided two sets on the first principal surface 22a of the second member 22. Thus, as illustrated in FIG. 3B, four first projections 22b are formed on the first principal surface 22a.

Further, the second member 22 includes, on the second principal surface 22d facing the third member 23, a pair of second projections 22e (second fins) extending in the lengthwise direction of the second member 22 (i.e., in the X-direction). The second guide portion 22f is provided by the pair of second projections 22e which are erected from the second principal surface 22d of the second member 22 and which are extended in the X-direction. The pair of second projections 22e are arranged at positions spaced in the Y-direction. A distance D2 between the pair of second projections spaced in the Y-direction is equal to or larger than a size W23 of the third member 23 in the Y-direction. With such a simple structure, the above-mentioned movement of the third member 23 in the X-direction can be facilitated.

Be it noted that the third member 23 can be smoothly and stably guided when the distance D2 between the pair of second projections 22e is substantially equal to the size of the third member 23 in its widthwise direction (i.e., in the Y-direction).

Parts of the second principal surface 22d, which are positioned outside the second guide portion 22f (second projections 22e), serve as resting portions 22g on which the solar modules 3 are rested. By moving the third member 23 in a state where the solar modules 3 are rested on the resting portions 22g, the third member 23 can be easily arranged at a middle between the solar modules 3 adjacent to each other in the X-direction. Therefore, the solar modules can be easily installed in a good external appearance as illustrated in FIG. 1C.

Particularly, the mounting member 4 may be installed such that, as illustrated in this embodiment, the lengthwise direction of the first member 21 is parallel to the direction in which the roof is sloped. In that case, when the solar modules 3 are successively arranged from the eave side to the ridge side, the second member 22 and the third member 23 are more surely avoided from sliding and shifting, due to the dead loads, etc., from positions where those members are to be arranged. As a result, installation accuracy and installation efficiency can be further improved.

Moreover, in this embodiment, the size of the second member 22 in its lengthwise direction (i.e., in the X-direction) may be smaller than the size of the solar module 3 in the X-direction, more specifically, the size of the frame 12 in the X-direction which is disposed as an outer frame of the solar module 3. This enables the mounting member 4 to be stably arranged at the corners of the solar modules 3.

The size of the second member 22 in its lengthwise direction (i.e., in the X-direction) may be smaller than ½ of the size of the solar module 3 in the X-direction. The second member 22 described above can be manufactured by using a material and a method similar to those for the first member 21.

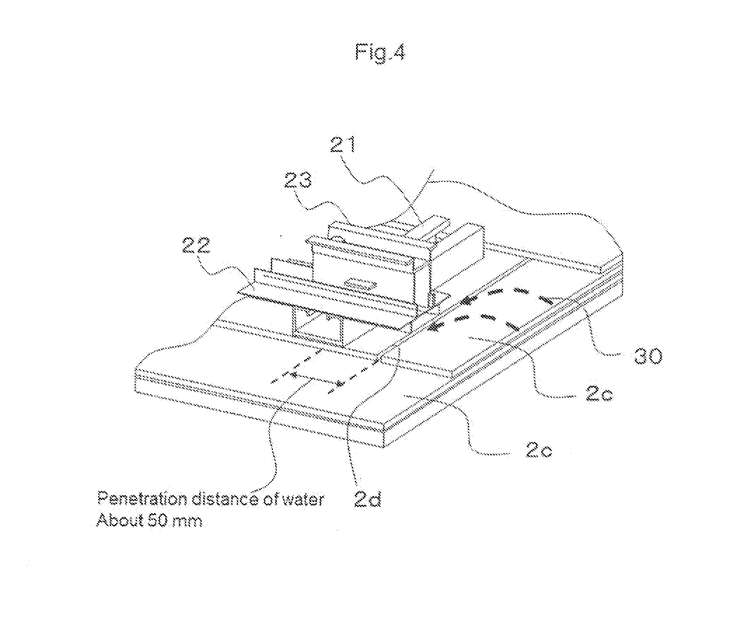

Further, the size of the second member 22 in its lengthwise direction (i.e., in the X-direction) may be 50 mm or longer. In this connection, as illustrated in FIG. 4, the first member 21 is preferably fixed with a distance of 50 mm or longer being left from an abutting portion 2d. With such an arrangement, penetration of water into the inner side of the base structure 2 due to the capillary phenomenon along the wood screws 25 can be reduced. For that reason, the size of the second member 22 in the x-direction may be 100 mm or longer.

Next, the third member 23 is a rail having a substantially T-shaped cross-section. The third member 23 is assembled such that the lengthwise direction of the third member 23 is parallel to the lengthwise direction of the second member 22 and the lengthwise direction of the third member 23 is perpendicular to the lengthwise direction of the first member 21′.

To describe in more detail, the third member 23 includes an upper surface portion 23a, an elongate hole 23b, side walls 23c, press-fixing portions 23d, and protruded portions 23e. The elongate hole 23b is formed in the upper surface portion 23a. The press-fixing portions 23d are plate-like portions extending outwards from upper ends of the side walls 23c in the Y-direction and are provided over the entire length of the third member 23 in its lengthwise direction. The protruded portions 23e are plate-like portions protruding outwards from substantially midpoints of the side walls 23c in the Y-direction and have a size corresponding to about ⅓ of the size of the third member 23 in its lengthwise direction.

The elongate hole 23b enables the third member 23 to be moved within the range, over which the elongate hole 23b is formed in the third member 23, in a state where the fixing member 24 is loosened while it remains attached in place.

The press-fixing portion 23d can fixedly clamp the frame 12 of the solar module 3 in cooperation with the resting portion 22g of the second member 22. A spacing (spacing in the Z-direction) L1 between the press-fixing portion 23d and the resting portion 22g, in particular, on the side claming the eave side of the solar module 3, is required to be set slightly larger than a size L2 of the frame 12 of the solar module 3 in the Z-direction. This facilitates the work for mounting the solar modules 3 to the sloped surface sloping in the Y-direction.

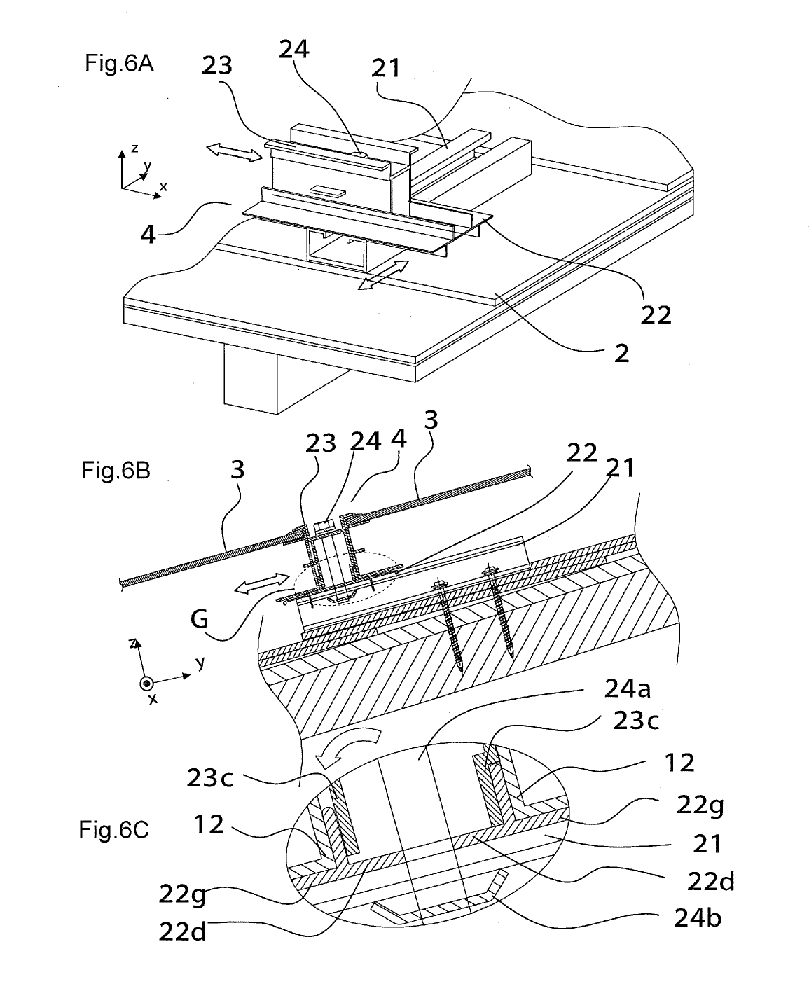

In addition to that the spacing L1 is larger than the size L2, in this embodiment, sizes of the two side walls 23c extending downwards from the upper surface portion 23a may differ from each other in the Z-direction as illustrated in FIG. 6C. Stated another way, in the state after the fixing member 24 has been mounted, a spacing L1-1 between the resting portion 22g positioned on the eave side of the solar module and the press-fixing portion 23d is larger than a spacing L1-2 between the resting portion 22g positioned on the ridge side of the solar module and the press-fixing portion 23d. More specifically, the side wall 23c positioned on the eave side contacts the second principal surface 22d of the second member 22, while the side wall 23c positioned on the ridge side does not contact the first principal surface 22d of the second member 22. With such a structure, when the solar module 3 on the eave side, which has been previously mounted, is fixed from the ridge side by using the mounting member 4, the mounting member 4 can be slid to the desired position along the sloping direction. Furthermore, when the mounting member 4 arranged at the desired position is fixed by the fixing member 24, the press-fixing portion 23d is inclined toward the eave side, whereby the solar module 3 can be more tightly fixed by the mounting member 4.

Each of the protruded portions 23e serves as a guide portion for adjusting the spacing between the solar modules 3 in the Y-direction when the solar modules 3 are mounted to the mounting members 4, thereby improving workability. In other words, the protruded portion 23e is arranged in a state sandwiched between the solar modules 3 adjacent to each other in the Y-direction. Accordingly, the spacing between the adjacent solar modules 3 can be easily held constant and the solar modules can be arrayed in a good external appearance.

The third member 23 described above can be manufactured by using a material and a method similar to those for the first member 21.

In this embodiment, the size of the third member 23 in the Y-direction is smaller than the size of the second member 22 in the X-direction. Hence, the third member 23 can be stably moved on the second member 22.

The fixing member 24 includes a bolt 24a and a bolt lock 24b. The bolt 24a is inserted through both the elongate hole 23b of the third member 23 and the bolt hole 22h of the second member 22, and it is fixedly held by the bolt lock 24b on the inner side than the gap 21d of the first member 21. With such an arrangement, when the fixing member 24 is in the loosened state, the second member 22 is movable in the lengthwise direction of the first member 21 (i.e., in the Y-direction) and the third member 23 is movable in the lengthwise direction of the second member 22 (i.e., in the X-direction). From the viewpoint of corrosion resistance, the fixing member 24 is made of stainless steel or hot-dip galvanized steel. The bolt lock 24b can be manufactured by pressing or tapping.

The wood screws 25 are inserted through the through-holes 21b of the first member 21, and they fix the first member 21 to the base structure 2. The wood screws 25 can also be made of stainless steel or hot-dip galvanized steel.

The adhesive member 26 is attached to the principal surface 21a of the first member 21 and is stuck to the base structure 2. Therefore, the adhesive member 26 serves to protect the surroundings of the fixed positions of the wood screws 25 against rain and moisture when the first member 21 is fixed to the base structure 2. The adhesive member 26 can be prepared by cutting, e.g., an adhesive sheet of silicone sealant or butyl, into the form of strip.

<Installation Method>

Installation procedures for the solar array 101 according to this embodiment will be described below. First, a predetermined position where each mounting member 4 is to be installed is marked on the base structure 2 by using an ink pot, for example. At that time, from the viewpoint of reducing penetration of water, the predetermined position is selected such that the wood screws 25 for the mounting member 4 are fixed to the rafter 2c at a position other than the abutting portion 2d of the shingle 2a constituting the base structure 2. In so selecting the fixing position, because the wood screws 25 are fixed to the rafter 2c that is a main structural member of a house, the strength in fixing the mounting member 4 to the base structure 2 is increased.

Then, the mounting member 4 is assembled by loosely fixing the first member 21, the second member 22, and the third member 23 in the positional relationship, illustrated in FIG. 3C, with the fixing member 24, and attaching the adhesive member 26 to the principal surface 21a of the first member 21. Further, the mounting member 4 is bonded to the base structure 2 by using the adhesive member 26 in alignment with the mark put on the base structure 2, and it is fixed to the base structure 2 by using the wood screws 25.

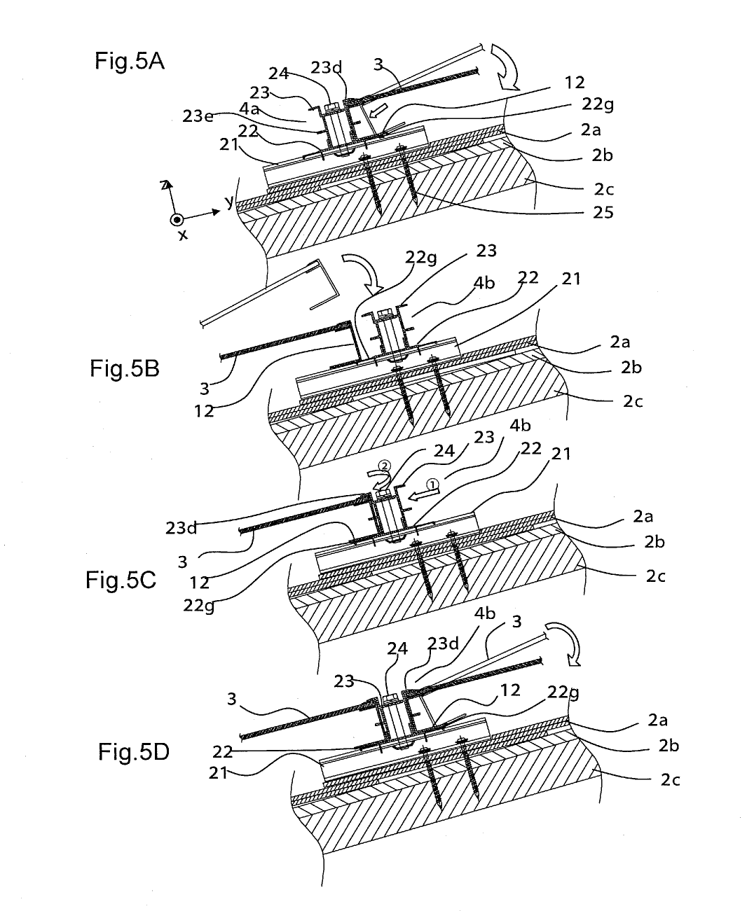

Next, as illustrated in FIG. 5C, the fixing member 24 of each of mounting members 4a in the first row, counting from the eave side of the base structure 2, is tightly fastened to fix the mounting member 4a, thereby fixing the relative positions of the second member 22 and the third member 23. At that time, the fixed position of the mounting member 4a is adjusted such that, as illustrated in FIG. 1C, the protruded portion 23e of the third member 23 is located between the solar modules 3 adjacent to each other in the X-direction. Then, the frame 12 on the eave side of the solar module 3 is inserted to the gap between the press-fixing portion 23d and the resting portion 22g.

Because, as described above, the spacing L1 between the press-fixing portion 23d and the resting portion 22g, which cooperatively hold the eave side of the solar module 3, is slightly larger than the frame 12 of the solar module 3, the solar module 3 can be smoothly inserted to the gap between the press-fixing portion 23d and the resting portion 22g without loosening the fixing member 24.

Next, as illustrated in FIG. 5B, the solar module 3 is laid down toward the base structure 2 and the frame 12 of the solar module 3 is rested on the resting portion 22g of a mounting member 4b in the second row.

Then, as illustrated in FIG. 5C, the second member 22 of the mounting member 4b in the second row is moved toward the eave side in the Y-direction along with the third member 23, whereby the ridge side of the solar module 3 is held between the press-fixing portion 23d and the resting portion 22g of the mounting member 4b. At that time, the position of the second member 22 in the X-direction is also controlled to adjust the fixed position thereof such that the protruded portion 23e is located between two solar modules 3 adjacent to each other in the X-direction.

Then, the fixing member 24 of the mounting member 4b in the second row is more tightly fastened to fix the ridge side of the solar module 3 by the mounting member 4b.

The solar modules 3 in the second and subsequent rows can be installed similarly to the installation method for the solar module 3 in the first row, and hence duplicate description is not repeated (see FIG. 5D).

Further, in the mounting member 4 according to this embodiment, as illustrated in FIG. 6A, the third member 23 is movable in the X-direction. Therefore, after installing the first member 21 to be away from the position possibly causing deterioration of water-proof, e.g., the position of the abutting portion 2d of the shingle 2a, the third member 23 can be moved to the desired position and the solar module 3 can be fixed at the desired position.

Also, since the second member 22 and the third member 23 are movable on the first member 21 in the Y-direction as illustrated in FIG. 6B, various solar modules 3 having different sizes in the Y-direction can be fixed by using one type of the mounting member 4.

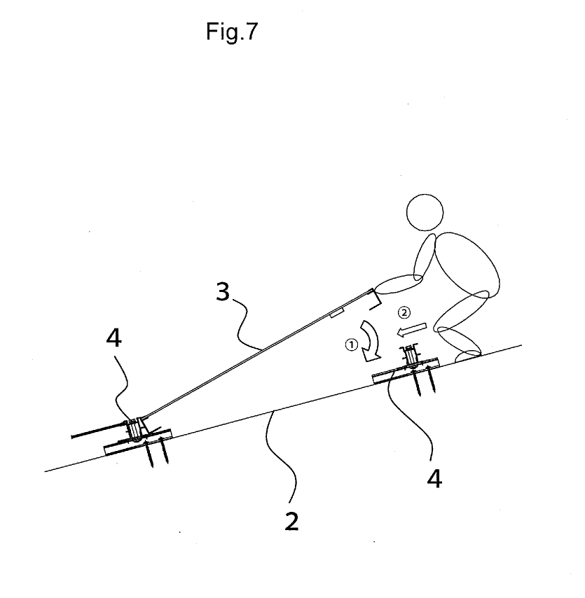

Moreover, as illustrated in FIG. 7, after resting the solar module 3 on the first member 21, the second member 22 and the third member 23 can be moved in the Y-direction for clamping and fixing of the solar module 3. Accordingly, a damage of the solar elements 17 in the solar module 3 possibly caused by a worker stepping on the solar module 3 during the work can be reduced.

The solar module 3 to which the present invention can be applied is not limited to the super-straight structure type described in the foregoing embodiment. The present invention is also applicable to other various structures, such as the glass package structure and the substrate structure.

While the foregoing embodiment has been described, by way of example, in connection with the solar array 101 that is installed on the sloped surface, the installation state is not limited to the illustrated one. The solar array 101 may be installed on, e.g., a horizontal surface.

### Second Embodiment

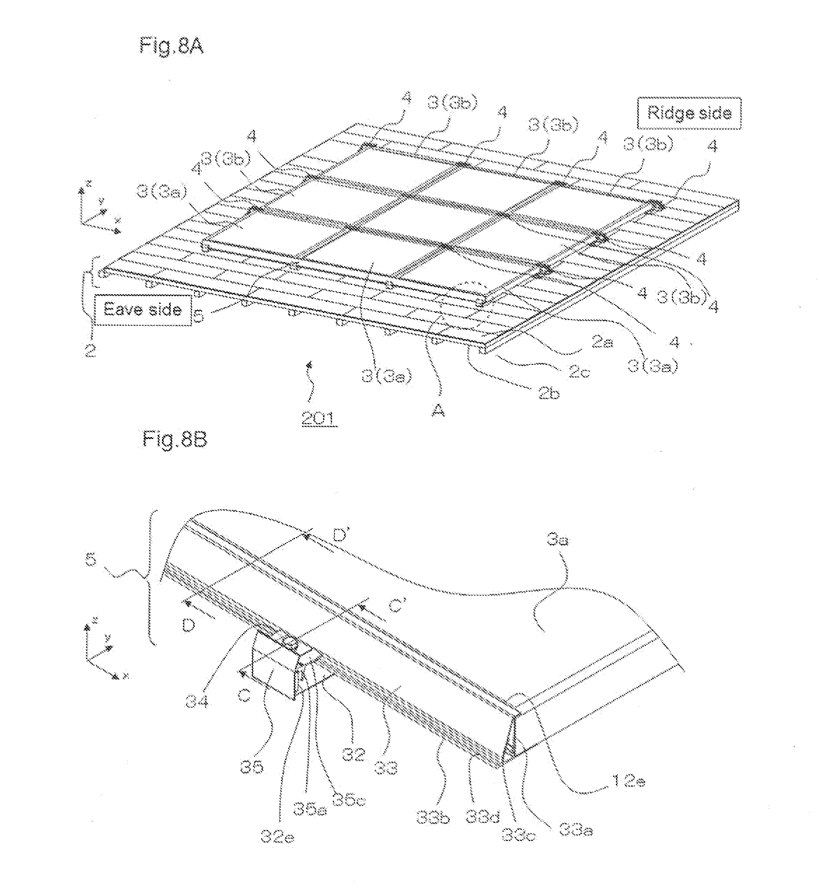

A solar array 201 according to a second embodiment will be described in detail below with reference to FIGS. 8 to 10. Be it noted that description of similar components to those in the first embodiment is omitted.

<Solar Array>

As illustrated in FIG. 8, the solar array 201 according to this embodiment further includes an eave-side member 5 for fixing an eave-side frame 12e of the solar module 3 arranged at a lowermost position in the Y-direction in which the solar array 201 is sloped.

Also in this embodiment, as illustrated in FIG. 8, a sloping direction of the base structure 2 is called the Y-direction, a direction normal to the base structure 2 is called the Z-direction, and a direction orthogonal to both the Y-direction and the Z-direction is called the X-direction hereinafter. Further, of the solar modules 3 adjacent to each other in the Y-direction, the one positioned on the lowermost side (i.e., the side nearest to the eave) is called a first solar module 3a, and the solar modules 3 positioned other than the lowermost side are each called a second solar module 3b.

<Eave-Side Member>

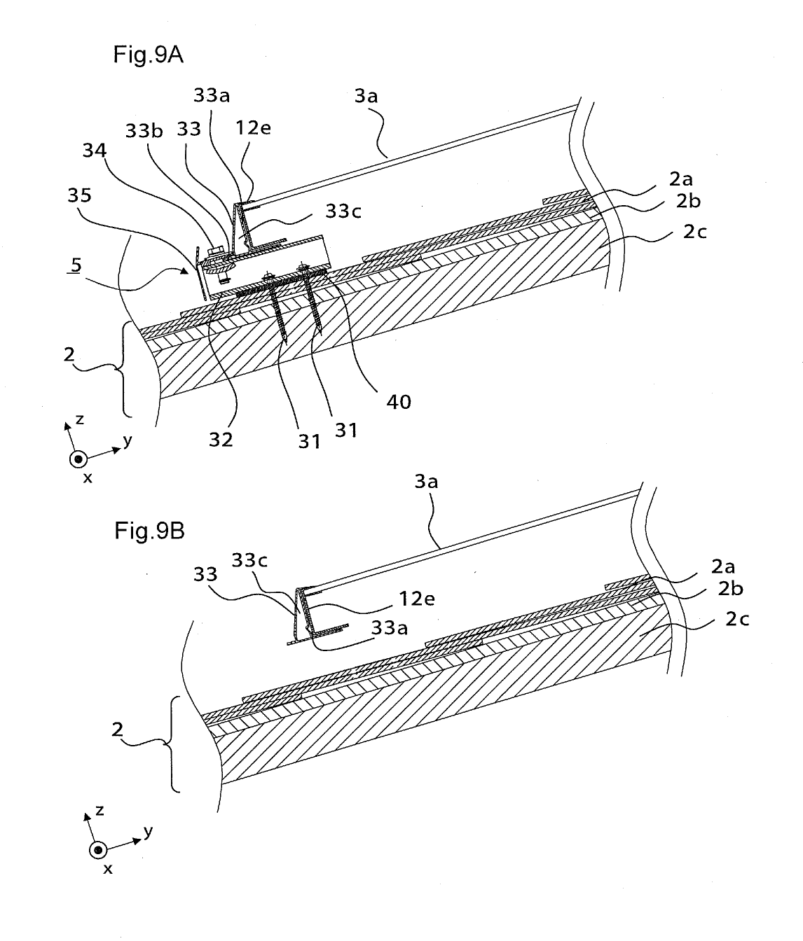

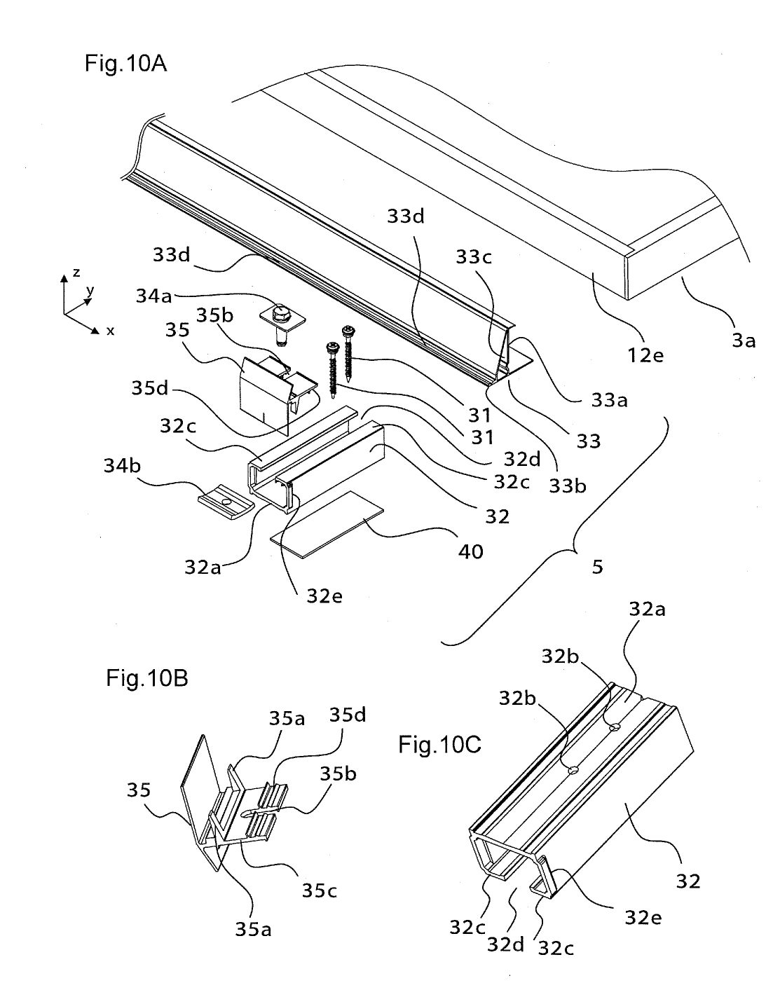

The eave-side member 5 for supporting the eave side of the first solar module 3a will be described in detail with reference to FIGS. 9 and 10 in addition to FIG. 8.

In the solar array 201 according to this embodiment, as illustrated in FIGS. 8, 9 and 10, the eave-side member 5 includes a base member (support) 32, a protective member 33, and an engagement member 35. The protective member 33 is fixed onto the base member 32 by using both a screw member 34 and the engagement member 35. More specifically, one protective member 33 is fixed by a plurality of base members 32, which are elongate in the sloping direction and which are fixed onto the sloped surface of the base structure 2.

The eave-side frame 12e of the first solar module 3a is fitted and fixed to a later-described rail groove 33a of the protective member 33. In more detail, as illustrated in FIG. 8B, a lower-side portion of the first solar module 3a, which is positioned on the lowermost side in the Y-direction among the plural solar modules 3, is received in the protective member 33, and the protective member 33 is fixed to the base structure 2.

First, the protective member 33 is described in detail. As illustrated in FIG. 8B, the protective member 33 is a long member extending in the X-direction. The size of the protective member 33 in its lengthwise direction is substantially the same as that of one or plural solar modules 3 in the X-direction.

In this embodiment, as illustrated in FIG. 10A, the protective member 33 includes a body 33h, a rail groove 33a, a clamped member 33b, and a hollow portion 33c.

The rail groove 33a is opened in a direction facing the eave-side frame 12e of the solar module 3. The rail groove 33a is elongate in the X-direction. Further, the size of the rail groove 33a in the Z-direction is substantially the same as that of the eave-side frame 12e in the Z-direction. Therefore, the solar module 3 can be fixed to the protective member 33 by fitting the eave-side frame 12e to the rail groove 33a.

The clamped portion 33b is extended on the side oppositely away from the rail groove 33a. The clamped portion 33b can be fixed onto the base member 32 in a state clamped between the base member 32 and the engagement member 35 both described later. More specifically, the clamped portion 33b includes a recess 33d engaging with the engagement member 35.

The hollow portion 33c is a space adjacent to the rail groove 33a. As illustrated in FIG. 10A, the protective member 33 has a closed cross-section. In other words, the hollow portion 33c is positioned adjacently on the eave side of the rail groove 33a and provides a space defined in the closed cross-section.

Thus, since the protective member 33 includes the rail groove 33a receiving one side portion of the solar module 3a and the hollow portion 33c formed in the body and extending in the lengthwise direction of the rail groove 33a, the eave-side frame 12e is reinforced and the solar module can be more surely avoided from being deformed or slipping off from the solar panel 11 when snow falls or drops.

The base member 32 will be described in detail below. The base member 32 has a similar shape to that of the first member 21 in the solar array 101 according to the above-described first embodiment. More specifically, as illustrated in FIG. 10C, the base member 32 includes a principal surface 32a, through-holes 32b, resting portions 32c, a gap 32d, and third projections 32e.

The through-holes 32b are formed in the principal surface 32a for insertion of wood screws 31 therethrough. The base member 32 is fixed to the base structure 2 by the wood screws 31 inserted through the through-holes 32b.

The principal surface 32a has a recessed and/or projected portion extending in the lengthwise direction of the base member 32. With the principal surface 32a having the recessed and/or projected portion, a similar advantageous effect to that described above in connection with the first member 21 can be obtained.

The base member 32 has a substantially U-shaped cross-section, and the resting portions 32c are extended from both sides of an opening of the U-shaped cross-section. The gap 32d is formed between the resting portions 32c. The resting portions 32c support the protective member 33.

The third projections 32e are disposed on lateral surfaces of the base member 32 and are engageable with stopper portions 35a of the engagement member 35 described below.

The engagement member 35 is now described in detail. The engagement member 35 includes the stopper portions 35a, a U-shaped hole 35b, a clamping portion 35c, and fourth projections 35d.

The screw member 34 is inserted through the U-shaped hole 35b. The clamping portion 35c clamps the protective member 33 in cooperation with the base member 32. The stopper portions 35a are engageable with the third projections 32e on the lateral surfaces of the base member 32, respectively, and the clamping portion 35c of the engagement member 35 is engageable with the recess 33d in the clamped portion 33b of the protective member 33.

Further, as illustrated in FIG. 10, the engagement member 35 is fixed to the resting portions 32c of the base member 32 by the screw member 34. By fastening the screw member 34, the recess 33d in the protective member 33 and the fourth projections 35d of the engagement member 35 are engaged with each other, and the clamped portion 33b of the protective member 33 is clamped by the resting portions 32c of the base member 32 and the engagement member 35. As a result, the protective member 33 can be fixed onto the base member 32. At that time, since the third projections 32e of the base member 32 and the stopper portions 35a are engaged with each other, the protective member 33 can be more surely avoided from dropping.

The base member 32, the engagement member 35, and the protective member 33, described above, can be manufactured by a similar manufacturing method to that described above for the first member 21.

Further, the screw member 34 includes a bolt 34a and a bolt lock 34b. The bolt 34a is inserted through the U-shaped hole 35b of the engagement member 35 and is fixed by the bolt lock 34b on the inner side than the gap 32d of the base member 32. The structure and the material of the screw member 34 can be selected similarly to those of the above-described fixing member 4.

The wood screws 31 are inserted through the through-holes 32b in the base member 32, thereby fixing the base member 32 to the base structure 2. The structure and the material of the wood screws 31 can be selected similarly to those of the above-described wood screws 25.

An adhesive member 40 has the function of sealing off the clearance between the base member 32 and the base structure 2 and reducing penetration of rain into the inner side of the base structure 2 along the wood screws 31. The adhesive member 40 is attached to the principal surface 32a of the base member 32 and is stuck to the base structure 2. Thus, when the base member 32 is fixed to the base structure 2, the adhesive member 40 protects the surroundings of the fixed positions of the wood screws 31 against rain and moisture. The structure and the material of the adhesive member 40 can be selected similarly to those of the above-described adhesive member 26.

<Installation Method>

An installation method for fixing the eave-side member 5 and fixing the first solar module 3a to the eave-side member 5 and the eave-side member 5 will be described below.

First, the base member 32 is fixed to an optionally selected position on the base structure 2 by the wood screws 31 with the adhesive member 40 interposed therebetween. The strength in fixing the base member 32 can be increased by selecting, as the fixed position of the base member 32, a position where the wood screws 31 for fixing the base member 32 are driven into the rafter of the base structure 2.

Next, the engagement member 35 is loosely mounted onto the base member 32 by the screw member 34. Thereafter, the clamped portion 33b of the protective member 33 is inserted between the clamping portion 35c of the engagement member 35 and the resting portions 32c of the base member 32.

Then, the recess 33d in the protective member 33 is engaged with the fourth projections 35d of the engagement member 35, and the protective member 33 is fixed onto the base member 21 by fastening the screw member 34.

Next, the eave-side frame 12e of the first solar module 3a is inserted and fixed to the rail groove 33a of the fixed protective member 33.

As described above, the solar array 201 according to this embodiment has a structure that the eave-side frame 12e of the first solar module 3a is inserted and fixed to the rail groove 33a of the protective member 33. Therefore, when snow is deposited on the eave side of the solar array 201 and a load in a torsional direction is applied to the eave-side member 5 and the eave-side frame 12e of the first solar module 3a, the protective member 33 and the eave-side frame 12e can be torsionally deformed as an integral unit. Accordingly, torsional rigidity of the solar array 201 on the eave side can be increased and torsional deformation of the solar array 201 can be reduced. As a result, it is possible to more surely avoid slipping-off of the solar panel 11 from the eave-side frame 12e and slipping-off of the first solar module 3a from the solar array 201. In addition, the load resistance performance of the solar array 201 against snow can be enhanced, and the reliability of the solar array 201 in a heavy snow area can be improved.

In the protective member 33 in this embodiment, as described above, the hollow portion 33c is formed adjacent to the rail groove 33a on the side oppositely away from the rail groove 33a. Because the hollow portion 33c is a space inside the protective member 33 having the closed cross-section, the torsional rigidity of the protective member 33 can be effectively increased, and the load resistance performance of the solar array 201 can be enhanced.

Further, in the solar array 201 of this embodiment, the eave sides of the first solar modules 3a are arrayed in a row in the X-direction along the protective member 33, and eave-side portions of the first solar modules 3a, which are most clearly viewed from the outer side, appear neat. As a result, an aesthetic impression in design of the solar array can be improved.

In this embodiment, the protective member 33 is held between the base member 32 and the engagement member 35. Therefore, the protective member 33 is movable in its lengthwise direction, and the base member 32 can be arranged and fixed at an optionally selected position with respect to the protective member 33. For example, the base member 32 can be fixed to the rafter 2c of the base structure 2 by the wood screws 31 in order to increase the mounting strength of the solar array 201. By arranging the base member 32 at such a position, the reliability of the solar array 201 can be improved.

Moreover, the installation method for the solar array 201 according to this embodiment is carried out by inserting the eave-side frame 12e of the first solar module 3a to the rail groove 33a of the protective member 33 from the ridge side. Accordingly, the worker can install the solar array 201 without stepping on the solar module 3. It is hence possible to reduce the occurrence of cracks in the solar elements 17 during the installation work, and to improve workability.

### Third Embodiment

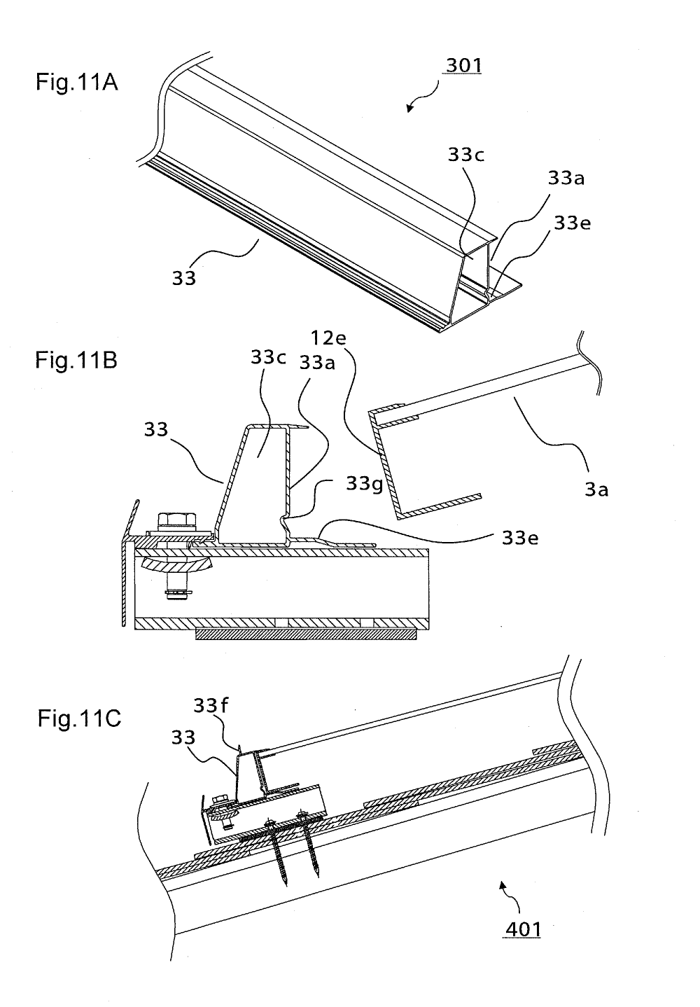

A solar array 301 according to a third embodiment will be described below with reference to FIGS. 11A and 11B.

As illustrated in FIG. 11A, the solar array 301 according to the third embodiment differs from the solar array 201 according to the second embodiment in structure of the protective member 33.

In this embodiment, the hollow portion 33c of the protective member 33 has a rectangular closed cross-section when it is cut in a direction perpendicular to the lengthwise direction of the rail groove 33a.

With the hollow portion 33c having the rectangular closed cross-section, the torsional rigidity is increased about twice in comparison with the hollow portion 33c having a triangular hollow cross-section that is substantially equal in size to the rectangular cross-section. As a result, the strength of the solar array 301 on the eave side can be greatly increased.

To improve an aesthetic impression in design, the hollow portion 23c may have a trapezoidal shape in cross-section, which has an oblique side on the eave side of the hollow portion.

Further, in the solar array 301 according to this embodiment, as illustrated in FIG. 11B, the rail groove 33a of the protective member 33 includes an inclined portion 33e. The inclined portion 33e is disposed in an opening of the rail groove 33a and has an inclined surface that is inclined downwards as illustrated. The inclined surface is inclined such that it comes closer to the base member 32 as the distance from a body 33h of the protective member 33 increases.

In this embodiment, the lower-side portion of the first solar module 3a is guided into the rail groove 33a by the inclined portion 33e. Further, as the eave-side frame 12e of the first solar module 3a is progressively inserted to the opening of the rail groove 33a, the eave-side frame 12e is more tightly clamped by the rail groove 33a.

In this embodiment, as illustrated in FIG. 11B, a bent portion 33g is further provided on the ridge side of the body 33h of the protective member 33. The bent portion 33g serves as a spring such that the rail groove 33a can clamp the eave-side frame 12e by an appropriate force. With the provision of the bent portion 23g, vibration of the first solar module 3a in a gap between the first solar module 3a and the rail groove 33a under a strong wind can be reduced, and hence transmission of unpleasant vibrations to the interior of a house can be reduced.

### Fourth Embodiment

A solar array 401 according to a fourth embodiment will be described below with reference to FIG. 11C.

As illustrated in FIG. 11C, the solar array 401 according to the fourth embodiment differs from the third embodiment in structure of the protective member 33.

In the fourth embodiment, the protective member 33 includes a third projection 33f on its upper surface. The third projection 33f is a snow-guard projection extending in the lengthwise direction of the rail groove 33a and projecting upwards of the protective member 33.

The third projection 33f thus provided serves as a snow guard capable of making snow laid on the solar array 401 less likely to slip down in large momentum. Since the protective member 33 has the structure with greater torsional rigidity as described above in the foregoing embodiment, the fourth embodiment can also realize a guard against snow while reducing damage of the solar array 401.

While the second to fourth embodiments of the present invention have been described above, the present invention is not limited to the foregoing embodiments. For example, the present invention may be applied to various sloped surfaces, such as outer wall surfaces or outer surfaces of buildings, other than the roof.

### Fifth Embodiment

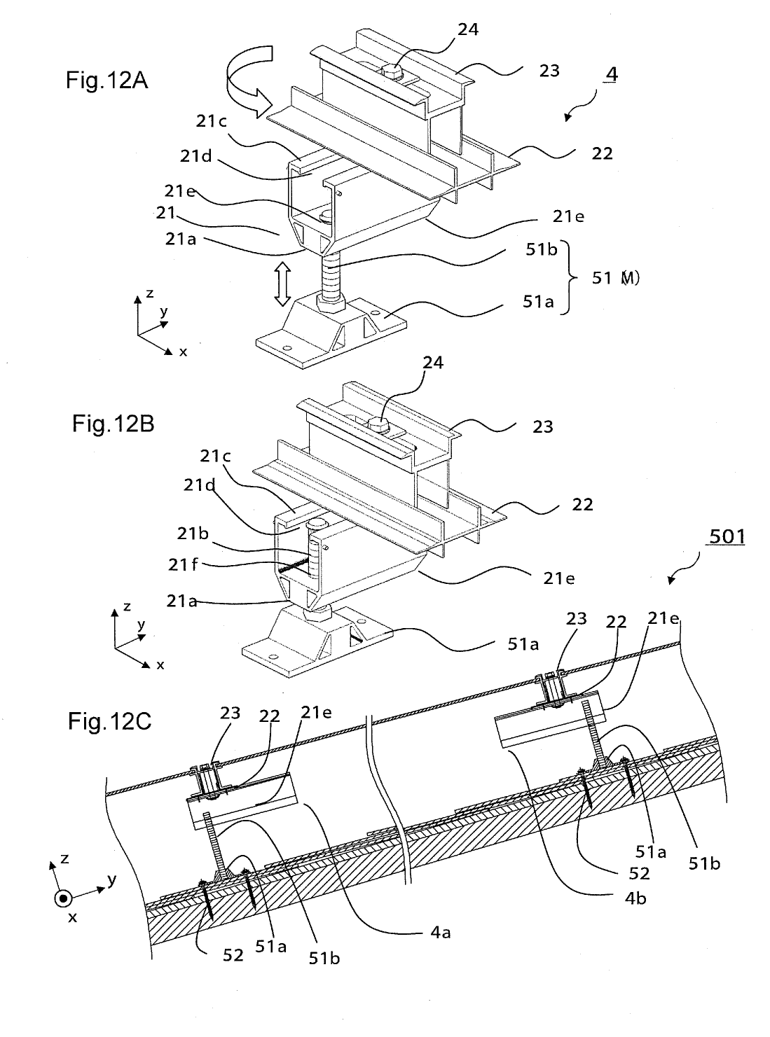

A solar array 501 according to a fifth embodiment will be described below with reference to FIGS. 12A to 12C.

In the fifth embodiment, the solar array 501 further includes a height adjusting means M. The height adjusting means M serves to move at least the first member 21, the second member 22, and the third member 23 of the mounting member 4 in the Z-direction. With the height adjusting means M capable of moving those members in the Z-direction, the solar modules 3 can be stably fixed with a good external appearance even when the installation surface, e.g., the roof surface, has irregularities. In particular, because the installed position of the mounting member 4 in the Z-direction can be finely adjusted, the solar modules 3 can be flatly installed even on the installation surface having irregularities that have been caused due to, e.g., distortions of the roof.

In this embodiment, the solar array 501 further includes a support member 51. The height adjusting means M is made up of a male screw (external threads) and a female screw (internal threads), which can mesh with each other and which are formed respectively on the support member 51 and in the first member 21.

More specifically, in this embodiment, the support member 51 includes a base portion 51a and a male screw 51b. The first member 21 includes a female screw portion 21e. The male screw 51b is inserted through the female screw portion 21e. The first member 21 is rotatable in an XY-plane with the male screw 51b being an axis of rotation.

Further, the base portion 51a of the support member 51 is fixed to the installation surface, e.g., the roof surface, by a plurality of wood screws 52. At that time, the wood screws 52 are fastened perpendicularly to the base portion 51a. The base portion 51a of the support member 51 can be made of, e.g., aluminum or stainless steel. The male screw 51b can be made of, e.g., steel or stainless steel.

Procedures for adjusting the height in this embodiment will be described below.

First, the support member 51 is fixed to a desired position on the installation surface.

Then, as illustrated in FIG. 12, the male screw 51b of the support member 51 is meshed with the female screw portion 21e of the first member 21 to which the second member 22 and the third member 23 are fixed in advance, thereby holding the first member 21 on the base portion 51a of the support member 51. A unit obtained by integrally assembling the second member 22 and the third member 23 with the first member 21 will be referred to as an “assembly” hereinafter.

The assembly (i.e., the first member 21, the second member 22, and the third member 23) is rotated about the male screw 51b as an axis of rotation such that the resting portions 21c of the first member 21 lie at a desired position in the height direction (Z-direction) from the installation surface. At that time, for each rotation of the assembly, the position of the assembly can be moved in the vertical direction by a height corresponding to a pitch of grooves of the male screw 51b. Therefore, the desired position can be obtained just by properly selecting the pitch of grooves of the male screw 51b depending on the height of irregularities in the installation surface.

FIG. 12A illustrates a state where the assembly is arranged at the highest position in the Z-direction, and FIG. 12B illustrates a state where the assembly is arranged at the lowest position in the Z-direction. The size of the male screw 51b is set such that, as illustrated in FIG. 12B, an upper end of the male screw 51b does not project upwards from the resting portions 21c of the first member 21 in the state where the assembly is at the lowest position in the Z-direction. By so setting the size of the male screw 51b, when the assembly is rotated, the male screw 51b can be less likely to interfere with the rotation of the assembly.

Further, in this embodiment, the base portion 51a of the support member 51 has an elongate shape extending in the sloping direction (Y-direction). The wood screws 52 for fixing the base portion 51a to the base structure 2 are arrayed along the sloping direction (Y-direction). Thus, the lengthwise direction of the base portion 51a is parallel to the lengthwise direction of the first member 21, and the base portion 51a is fixed to the sloped surface by the plural wood screws 52 that are arrayed in the lengthwise direction of the base portion 51a. With such a structure, the dead load of the solar module 3 acting in the Y-direction in which the solar module 3 is sloped can be firmly supported. As a result, the reliability of the solar array 501 can be increased.

Moreover, in this embodiment, as illustrated in FIGS. 12A to 12C, the female screw portion 21e is positioned on the side near an end of the first member 21 in its lengthwise direction (i.e., in the Y-direction). More specifically, the female screw 21e is formed at a position inwardly spaced by ¼ of the length of the first member 21 from the end of the first member 21 in its lengthwise direction. With such an arrangement, as comparatively illustrated by a mounting member 4a and a mounting member 4b in FIG. 12C, a region where the second member 22 is movable in the X-direction can be sufficiently provided with respect to the size of the first member 21 by rotating the first member 21 such that the first member 21 is positioned relatively long toward the eave side or the ridge side from the support member 51. Accordingly, the component cost can be reduced and a wider movable region, i.e., a wider rotatable region, of the assembly can be ensured.

While the fifth embodiment has been described above in connection with the case where the first member 21 has the female screw and the support member 51 has the male screw, the embodiment is not limited to the illustrate one. For example, the first member 21 may have the male screw and the support member 51 may have the female screw.

### Sixth Embodiment

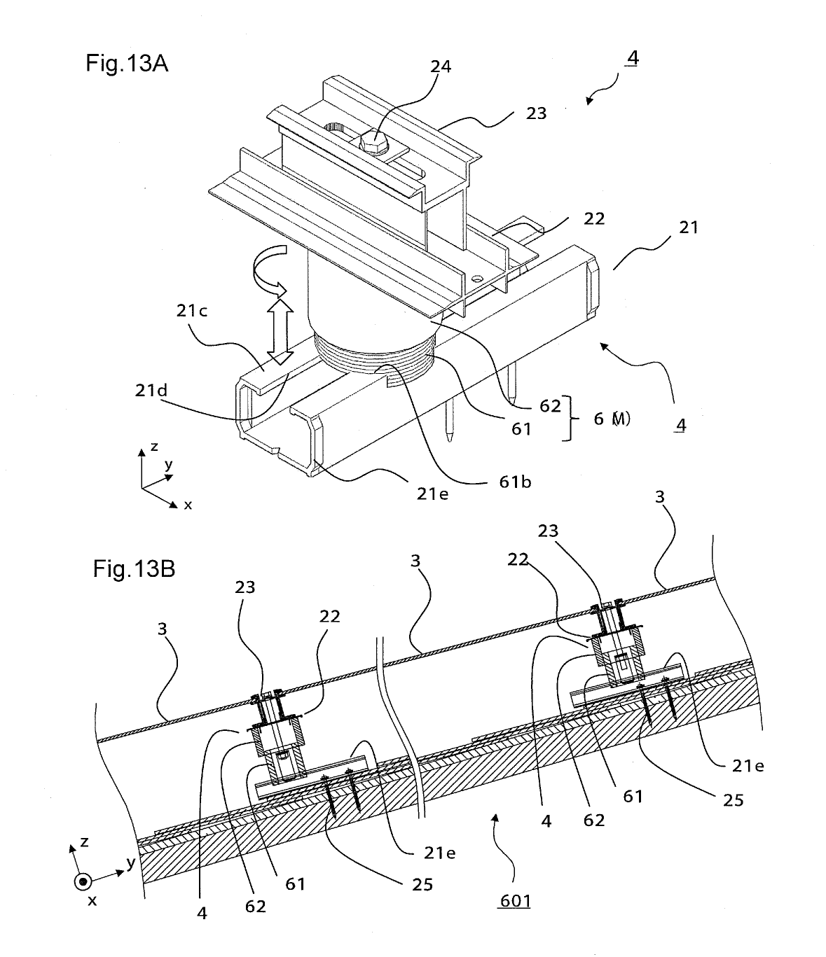

A solar array 601 according to a sixth embodiment will be described below with reference to FIG. 13A to 13C. The solar array 601 according to the sixth embodiment differs from the fifth embodiment in structure of the height adjusting means M.

In the sixth embodiment, the height adjusting means M is constituted by a cylindrical fourth member 6 arranged between the first member 21 and the second member 22. More specifically, the fourth member 6 includes a first cylindrical portion 61 and a second cylindrical portion 62, which can be meshed with each other. Each of the first cylindrical portion 61 and the second cylindrical portion 62 has a hollow cylindrical shape. For example, resin or aluminum can be used as materials of the first cylindrical portion 61 and the second cylindrical portion 62.

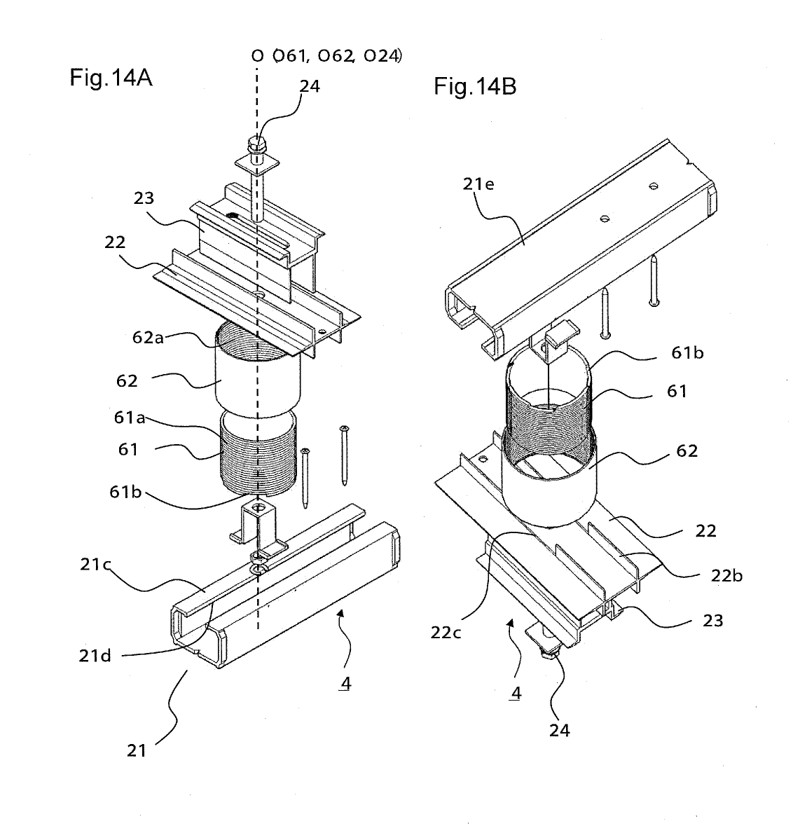

In this embodiment, as illustrated in FIGS. 14A and 14B, the first cylindrical portion 61 includes a first screw portion 61a on its outer peripheral surface, and the second cylindrical portion 62 include a second screw portion 62a formed in its inner peripheral surface and meshing with the first screw portion 61a. The first screw portion 61a is a male screw, and the second screw portion 62a is a female screw.

With such an arrangement, in this embodiment, the second member 22 and the third member 23 can be moved together in the height direction (Z-direction) by rotating the second cylindrical portion 62. In this embodiment, therefore, as in the fifth embodiment, the solar modules 3 can be flatly installed even on the installation surface having small irregularities that have been caused due to, e.g., distortions of the roof.

In this embodiment, the first cylindrical portion 61 is arranged on the first member 21, and the second member 22 is arranged on the second cylindrical portion 62. Further, the first cylindrical portion 61 includes, at its lower end, engagement portions 61b engaging with the first member 21. More specifically, the engagement portions 61b are engaged with both the pair of resting portions 21c and the gap 21d of the first member 21. With the engagement portions 61b described above, the first cylindrical portion 61 is movable in the lengthwise direction of the first member 21 (i.e., in the Y-direction), and the second member 22 and the third member 23 are movable in the lengthwise direction of the first member 21.

To ensure that the engagement portions 61b of the first cylindrical portion 61 are engaged with the first member 21, the outer diameter of the first cylindrical portion 61 is larger than the width of the gap 21d. Particularly, when the outer diameter of the first cylindrical portion 61 is larger than the size of the first member 21 in its widthwise direction (i.e., in the X-direction), the first member 21 can stably support the first cylindrical portion 61.

In this embodiment, as illustrated in FIG. 13B, an outer periphery of the second cylindrical portion 62 is fitted to the first guide portion 22c provided by the first projections 22b on the second member 22. As a result, dislocation of the fourth member 6 can be reduced.

Moreover, in this embodiment, as illustrated in FIG. 14A, a center line O61 of the first cylindrical portion 61, a center line O62 of the second cylindrical portion 62, and a center line O24 of the fixing member 24 are arranged on one linear line. Thus, in this embodiment, the height adjusting means M (i.e., the first cylindrical portion 61 and the second cylindrical portion 62) are positioned right below the second member 22 and the third member 23 unlike the fifth embodiment.

With such an arrangement, the dead load is applied in the axial direction of the first cylindrical portion 61 and the second cylindrical portion 62, and hence a moment does not occur unlike the fifth embodiment. Accordingly, the strength of the solar array 601 can be increased.

Be it noted that, as in this embodiment, the second member 22 is not always required to be arranged in direct contact with the first member 21. It is at least required that the first member 21, the second member 22, and the third member 23 are relatively movable in the X-, Y- and Z-directions as described above.

While the sixth embodiment has been described above in connection with the case where the first cylindrical portion 61 arranged on the lower side has the male screw at its outer periphery and the second cylindrical portion 62 arranged on the upper side has the female screw at its inner periphery, the embodiment is not limited to the illustrated one. It is just required that the male screw is formed on one of the first cylindrical portion 61 and the second cylindrical portion 62, and the female screw is formed in the other.

Additionally, the efficiency of the height adjusting operation is increased with the arrangement that, of the two cylindrical portions, the outer diameter of the cylindrical portion arranged on the upper side and rotated for adjusting the height is larger than that of the cylindrical portion arranged on the lower side.

While the height adjusting means M according to the embodiments have been described above, the height adjusting means M usable in the present invention are not limited to the illustrated ones.

### Seventh Embodiment

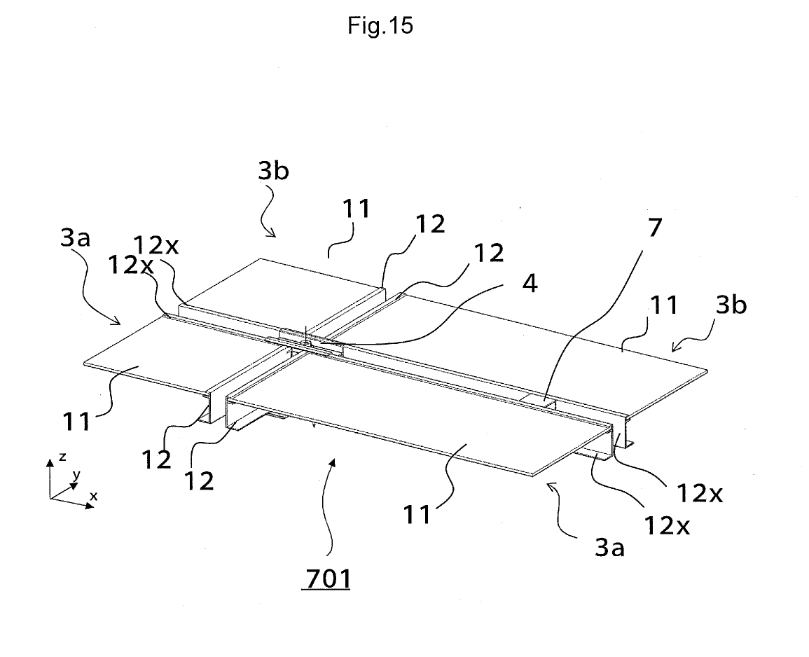

A solar array 701 according to a seventh embodiment will be described below with reference to FIG. 15. The solar array 701 according to the seventh embodiment differs from the solar array 1 according to the first embodiment in further including a spacer arranged between two solar modules 3a and 3b adjacent to each other in the Y-direction.

More specifically, as illustrated in FIG. 15, the solar array 701 includes a spacer 7 arranged between two solar modules adjacent to each other in the Y-direction. The spacer 7 is arranged in an intermediate portion of the solar module 3 in the X-direction that is perpendicular to the Y-direction. Stated another way, the spacer 7 is arranged between a frame 12x of the first solar module 3a, extending in the X-direction, and a frame 12x of the second solar module 3b, extending in the X-direction.

With such an arrangement, the spacer 7 can be mounted in place by a simple fitting operation, and the distance between the first solar module 3a and the second solar module 3b can be properly specified by the spacer 7. As a result, the solar panel 11 can be more surely avoided from slipping off from the frame 12, and good workability is ensured.

This embodiment increases the number of components of the solar array, but it increases the advantageous effect of reducing torsional deformation of the solar module 3. Therefore, this embodiment is preferably applied to the solar module 3 having a larger size in the X-direction.

The present invention is not limited to the above-described embodiments, and the present invention can be variously modified and changed within the scope of the invention. It is a matter of course that the present invention involves various combinations of the above-described embodiments.

### REFERENCE SIGNS LIST

1: solar array
2: base structure
2a: shingle
2b: sheathing
2c: rafter
2d: abutting portion
3: solar module
3a: first solar module
3b: second solar module
4: mounting member
5: eave-side member
11: solar panel
11a: light receiving surface
11b: light non-receiving surface
12: frame
12a: fitting portion
12b: upper surface of frame
12c: lower surface of frame
12d: lateral surface of frame
12e: eave-side frame
13: rear-surface protective member
14: light-transmissive base plate
15: filling material
16: inner lead
17: solar element
18: terminal box
21: first member
21a: principal surface
21b: through-hole
21c: resting portion
21d: gap
21e: female screw portion
22: second member
22a: first principal surface
22b: first projection
22c: first guide portion
22d: second principal surface
22e: second projection
22f: second guide portion
22g: resting portion
22h: bolt hole
23: third member
23a: upper surface portion
23b: elongate hole
23c: side wall
23d: press-fixing portion
23e: protruded portion
24: fixing member
24a: bolt
24b: bolt lock
25: wood screw
26: adhesive member
30: water route
31: wood screw
32: base member (support)
32a: principal surface
32b: through-hole
32c: resting portion
32d: gap
32e: third projection
33: protective member
33a: rail groove
33b: clamped member
33c: hollow portion
33d: recess
33e: inclined portion
33f: third projection
33g: bent portion
33h: body
34: screw member
34a: bolt
34b: bolt lock
35: engagement member
35a: stopper portion
35b: U-shaped hole
35c: clamping portion
35d: fourth projection
40: adhesive member
M: height adjusting means
51: support member
51a: base portion
51b: male screw
52: wood screw
6: sixth member
61: first cylindrical portion
61a: first screw portion
61b: engagement portion
62: second cylindrical portion
62a: second screw portion
7: spacer

1. A solar array comprising:
a plurality of solar modules arrayed along at least one of an X-direction and a Y-direction perpendicular to the X-direction in a not-overlapped state with rear surfaces of the solar modules being directed downwards; and
a mounting member arranged between corners of the solar modules adjacent to each other,
the mounting member including:
a first member extending in at least one of the X-direction and the Y-direction;
a second member positioned on the first member and including a support portion supporting the rear surface of the solar module;
a third member positioned on the second member and including a clamping portion clamping the solar module in cooperation with the support portion of the second member; and
a fixing member vertically penetrating through the second member and the third member and fixing the second member and the third member to the first member,
the second member and the third member being movable along a lengthwise direction of the first member.

2. The solar array according to claim 1, wherein the first member has an elongate shape with the Y-direction being a lengthwise direction thereof, and
before the second member and the third member are fixed to the first member by the fixing member, the second member is movable in the Y-direction and the third member is movable in the X-direction and the Y-direction.

3. The solar array according to claim 2, wherein the second member includes, on a first principal surface thereof facing the first member, a first guide portion guiding movement of the second member in the Y-direction.

4. The solar array according to claim 3, wherein the first guide portion is provided by a pair of first projections erected from the first principal surface of the second member and arranged in oppositely spaced relation in a widthwise direction of the first member, and
a distance between the pair of first projections in the widthwise direction of the first member is equal to or larger than a widthwise size of the first member.

5. The solar array according to claim 2, wherein the second member includes, in a second principal surface thereof facing the third member, a second guide portion guiding movement of the third member in the X-direction with respect to the second member, and
the third member includes a through-hole through which the fixing member is inserted, the through-hole allowing the third member to be moved in the X-direction before the third member is fixed to the first member.

6. The solar array according to claim 5, wherein the second guide portion is provided by a pair of second projections erected from the second principal surface of the second member and extending in the X-direction,
the pair of second projections are arranged at positions spaced in the Y-direction, and
a distance between the pair of second projections in the Y-direction is equal to or larger than a size of the third member in the Y-direction.

7. The solar array according to claim 5, wherein the through-hole is a hole elongate in the X-direction.

8. The solar array according to claim 1, wherein a size of the second member in the X-direction is smaller than a size of the solar module in the X-direction.

9. The solar array according to claim 1, wherein a size of the third member in the Y-direction is smaller than a size of the second member in the X-direction.

10. The solar array according to claim 1, wherein the third member further includes a protruded portion held between the solar modules adjacent to each other.

11. The solar array according to claim 1, wherein the plural solar modules of the solar array are arrayed at least along the Y-direction in which the solar array is sloped, and
the solar array further comprises a protective member supporting a lower-side portion of a first solar module, which is positioned on the lowermost side in the Y-direction among the plural solar modules.

12. The solar array according to claim 11, wherein the protective member includes a body, a rail groove being elongate in the X-direction and receiving the lower-side portion of the first solar module, and a hollow portion formed in the body and extending in a lengthwise direction of the rail groove.

13. The solar array according to claim 11, further comprising a plurality of supports elongate in the Y-direction, wherein the protective member is fixed to the supports.

14. The solar array according to claim 12, wherein the rail groove includes an inclined portion for guiding the lower-side portion of the first solar module into the rail groove.

15. The solar array according to claim 1, further comprising height adjusting means for moving at least the second member and the third member of the mounting member in a Z-direction that is orthogonal to the X-direction and the Y-direction.

16. The solar array according to claim 15, further comprising a support member arranged below the first member and supporting the first member, wherein the height adjusting means includes a male screw and a female screw, which are provided on the first member and the support member, respectively, and which are capable of meshing with each other.

17. The solar array according to claim 16, wherein the support member includes an elongate base portion extending in the Y-direction.

18. The solar array according to claim 15, wherein the height adjusting means is provided as a cylindrical fourth member arranged between the first member and the second member, and
the fourth member includes a first cylindrical portion having a first screw portion in an outer peripheral surface thereof, and a second cylindrical portion having a second screw portion in an inner peripheral surface thereof, the second screw portion meshing with the first screw portion.

19. The solar array according to claim 18, wherein the first cylindrical portion is arranged on the first member, and the second member is arranged on the second cylindrical portion, and
the first cylindrical portion includes, at a lower end thereof, an engagement portion engaging with the first member.

20. The solar array according to claim 18, wherein a center line of the first cylindrical portion, a center line of the second cylindrical portion, and a center line of the fixing member are arranged on one linear line.
